(19) United States
(12) Patent Application Publication
(10) Pub. No.: US 2025/0336847 A1
(43) Pub. Date: Oct. 30, 2025

(54) SEMICONDUCTOR MEMORY DEVICES

(71) Applicant: Samsung Electronics Co., Ltd., Suwon-si (KR)

(72) Inventors: Sanghyun SUNG, Suwon-si (KR); Jinwoo HAN, Suwon-si (KR)

(73) Assignee: Samsung Electronics Co., Ltd., Suwon-si (KR)

(21) Appl. No.: 19/008,823

(22) Filed: Jan. 3, 2025

(30) Foreign Application Priority Data
Apr. 26, 2024 (KR) 10-2024-0056306

(51) Int. Cl. H01L 23/62; H10B 12/00

(52) U.S. Cl. CPC H01L 23/62; H10B 12/315; H10B 12/488; H10B 12/50

(57) ABSTRACT

A semiconductor memory device includes a first stack structure including a memory cell region and an antifuse array region, the memory cell region including a plurality of memory cells and a plurality of cell capacitors, the plurality of memory cells being arranged three-dimensionally, and the antifuse array region including a plurality of antifuse cells that are arranged three-dimensionally; and a second stack structure on the first stack structure, the second stack structure including a core region and a peripheral circuit region, the core region at a location vertically overlapping the memory cell region, the core region being electrically connected to the memory cell region, and the peripheral circuit region at a location vertically overlapping the antifuse array region.

### CROSS-REFERENCE TO RELATED APPLICATION

This application is based on and claims priority under 35 U.S.C. § 119 to Korean Patent Application No. 10-2024-0056306, filed on Apr. 26, 2024, in the Korean Intellectual Property Office, the disclosure of which is incorporated by reference herein in its entirety.

### BACKGROUND

The inventive concepts relate to a semiconductor memory device, and more particularly, to a three-dimensional (3D) semiconductor memory device.

As demand for high performance electronics increases, electronic products are required to be miniaturized, multifunctional, and highly efficient. For example, high-capacity semiconductor memory devices and increased integration density is needed to provide the high-capacity semiconductor memory devices. A 3D semiconductor memory device that increases memory capacity by stacking a plurality of memory cells in a vertical direction on a substrate is being proposed.

When a defect occurs in some of the memory cells, a method of replacing a defective memory cell with a redundancy cell that is previously manufactured in the memory device is used. A repair operation using the redundancy cell is mainly performed by using an antifuse device. The antifuse device has a high resistance in an unprogrammed state and has a low resistance after a program operation. The antifuse device has a problem of occupying a relatively great area in a peripheral circuit region.

### SUMMARY

The inventive concepts provide a three-dimensional (3D) semiconductor memory device, which may improve the spatial efficiency of a chip by changing the arrangement of a peripheral circuit including an antifuse device.

According to an aspect of the inventive concepts, there is provided a semiconductor memory device including a first stack structure including a memory cell region and an antifuse array region, the memory cell region including a plurality of memory cells and a plurality of cell capacitors, the plurality of memory cells and the plurality of cell capacitors arranged three-dimensionally, and the antifuse array region including a plurality of antifuse cells arranged three-dimensionally, and a second stack structure on the first stack structure, the second stack structure including a core region and a peripheral circuit region, the core region at a location vertically overlapping the memory cell region, the core region being electrically connected to the memory cell region, and the peripheral circuit region at a location vertically overlapping the antifuse array region.

According to another aspect of the inventive concepts, there is provided a semiconductor memory device including a first stack structure including a plurality of memory cells and a plurality of antifuse cells, the plurality of memory cells on a first substrate and spaced apart from each other in a vertical direction, and the plurality of antifuse cells on the first substrate and spaced apart from each other in the vertical direction, and a second stack structure on the first stack structure, the second stack structure including a core region and a peripheral circuit region, the core region on a second substrate, the core region vertically overlapping and electrically connected to the plurality of memory cells, and the peripheral circuit region on the second substrate, the peripheral circuit region at a location vertically overlapping the plurality of antifuse cells, wherein the plurality of memory cells include a plurality of first semiconductor patterns extending in a first lateral direction, and the plurality of antifuse cells comprise a plurality of second semiconductor patterns extending in the first lateral direction and each respectively at a same vertical level as a corresponding first semiconductor pattern of the plurality of first semiconductor patterns.

According to another aspect of the inventive concepts, there is provided a semiconductor memory device including a first substrate, a plurality of first semiconductor patterns on the first substrate, the plurality of first semiconductor patterns extending in a first lateral direction, a word line on at least portions of each of the plurality of first semiconductor patterns, the word line extending in a second lateral direction, a bit line connected to first end portions of each of the plurality of first semiconductor patterns, the bit line extending in a vertical direction, a plurality of cell capacitors respectively connected to second end portions of the plurality of first semiconductor patterns, a plurality of second semiconductor patterns spaced apart from the plurality of first semiconductors patterns on the first substrate, the plurality of second semiconductor patterns extending in the first lateral direction, an antifuse word line on at least portions of each of the plurality of second semiconductor patterns, the antifuse word line extending in the second lateral direction, a second substrate at a higher vertical level than the first substrate, and a peripheral circuit transistor on the second substrate, the peripheral circuit transistor vertically overlapping the antifuse word line.

### BRIEF DESCRIPTION OF THE DRAWINGS

Embodiments will be more clearly understood from the following detailed description taken in conjunction with the accompanying drawings in which:

FIG. 1 is a block diagram of a semiconductor memory device according to some embodiments;

FIG. 2 is a circuit diagram of a memory cell array shown in FIG. 1;

FIG. 3 is a circuit diagram of the antifuse cell array shown in FIG. 1;

FIG. 4 is a perspective view of a semiconductor memory device according to some embodiments;

FIG. 5 is a perspective view of a memory cell region of a first stack structure of FIG. 4;

FIG. 6 is a perspective view of an antifuse array region of the first stack structure of FIG. 4;

FIG. 7 shows cross-sectional views taken along lines A1-A1′ of FIGS. 5 and A2-A2′ of FIG. 6;

FIG. 8 is a cross-sectional view taken along line B1-B1′ of FIG. 5;

FIG. 9 is an enlarged view of portion CX1 of FIG. 7;

FIG. 10 is an enlarged view of portion CX2 of FIG. 7;

FIG. 11 is a layout diagram of a semiconductor memory device according to some embodiments;

FIG. 12 is a schematic view of a voltage-current curve of an antifuse cell included in a semiconductor memory device according to some embodiments;

FIG. 13 is a cross-sectional view of a semiconductor memory device according to some embodiments;

FIG. 14 is a cross-sectional view of a semiconductor memory device according to some embodiments;

FIG. 15 is a cross-sectional view of a semiconductor memory device according to some embodiments; and

FIGS. 16A, 16B, 17A, 17B, 18A, 18B, 19A, 19B, 20 to 22, 23A, 23B, 24A, and 24B are schematic views of a method of manufacturing a semiconductor memory device, according to some embodiments.

### DETAILED DESCRIPTION OF THE EMBODIMENTS

Hereinafter, embodiments will be described in detail with reference to the accompanying drawings. Like reference numerals in the drawings denote like components, and sizes of components in the drawings may be exaggerated for convenience of explanation. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

It will also be understood that such spatially relative terms, such as “above,” “top,” “vertical,” “lateral,” etc., are intended to encompass different orientations of the device in use or operation in addition to the orientation depicted in the figures, and that the device may be otherwise oriented (rotated 90 degrees or at other orientations) and the spatially relative terms used herein interpreted accordingly.

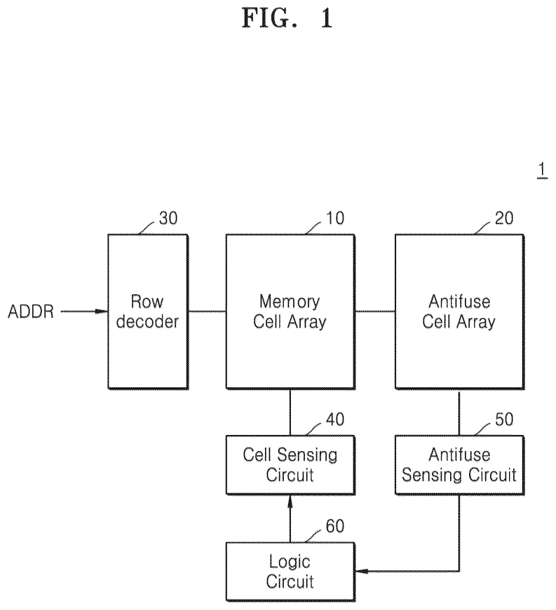

FIG. 1 is a block diagram of a semiconductor memory device according to some embodiments.

Referring to FIG. 1, a semiconductor memory device 1 may include a memory cell array 10, an antifuse cell array 20, a row decoder 30, a cell sensing circuit 40, an antifuse sensing circuit 50, and a logic circuit 60.

The memory cell array 10 may include a plurality of word lines and a plurality of memory cells connected to the plurality of word lines. For example, the plurality of memory cells connected between the plurality of word lines and a plurality of bit lines. The plurality of memory cells may be arranged in columns and rows. The plurality of memory cells may include dynamic random-access memory (DRAM) cells. The plurality of word lines of the memory cell array 10 may be connected to the row decoder 30.

The antifuse cell array 20 may include a plurality of antifuse cells connected between a plurality of antifuse word lines and a plurality of antifuse bit lines. The plurality of antifuse cells may be configured to store information about a defective cell included in the memory cell array 10. For instance, address data about the defective cell may be electrically programmed in the antifuse cells.

The row decoder 30 may be configured to select a word line by decoding an externally input address ADDR, and read data from an antifuse cell connected to the selected word line and a memory cell connected to the selected word line.

The cell sensing circuit 40 may be configured to select some bit lines, from among the plurality of bit lines of the memory cell array 10, in response to a control signal provided from the logic circuit 60.

The antifuse sensing circuit 50 may be configured to sense defective cell information stored in antifuse cells of the antifuse cell array 20, which are connected to the selected word line, and to amplify the defective cell information. The antifuse sensing circuit 50 may provide a defective column address read from the antifuse cell array 20 to the logic circuit 60.

The logic circuit 60 may be configured to determine whether the externally input address ADDR matches an address of the defective cell, which is stored in the plurality of antifuse cells. When the externally input address ADDR matches the address of the defective cell, the logic circuit 60 may read defective cell information from an antifuse cell corresponding to the defective cell and provide the defective cell information to the outside.

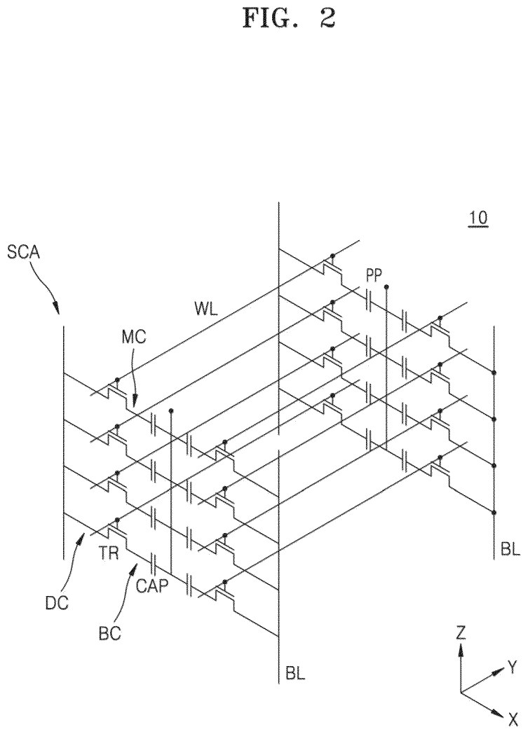

FIG. 2 is a circuit diagram of the memory cell array 10 shown in FIG. 1.

Referring to FIG. 2, the memory cell array 10 may include a plurality of sub-cell arrays SCA. The plurality of sub-cell arrays SCA may be apart from each other in a second lateral direction Y.

The sub-cell array SCA may include a plurality of bit lines BL, a plurality of word lines WL, and a plurality of memory cells MC. Each of the plurality of memory cells MC may include one cell transistor TR and one cell capacitor CAP connected to the cell transistor TR. Each of the plurality of memory cells MC may have a 1 transistor-1 capacitor (1T1C) structure.

The plurality of word lines WL may extend in the second lateral direction Y and be apart from each other in a first lateral direction X and a vertical direction Z. The plurality of bit lines BL may extend in the vertical direction Z and be apart from each other in each of the first lateral direction X and the second lateral direction Y. One cell transistor TR may be between one word line WL and one bit line BL.

A gate of the cell transistor TR may be connected to a respective one of the plurality of word lines WL, and a source of the cell transistor TR may be connected to a respective one of the bit lines BL through a first contact DC. The cell transistor TR may be connected to the cell capacitor CAP through a second contact BC. For example, a drain of the cell transistor TR may be connected to a first electrode of the cell capacitor CAP through the second contact BC, and a second electrode of the cell capacitor CAP may be connected to a plate electrode PP.

In one sub-cell array SCA, a plurality of cell transistors TR may be located at locations overlapping each other in the vertical direction Z. In one sub-cell array SCA, a plurality of cell capacitors CAP may be located at locations overlapping each other in the vertical direction Z. One cell transistor TR and one cell capacitor CAP may be arranged in series at the same vertical level, and a plurality of memory cells MC, each of which includes one cell transistor TR and one cell capacitor CAP, may be stacked in the vertical direction Z. The storage capacity of the sub-cell array SCA may vary depending on the number and/or layer number of memory cells MC stacked in the vertical direction Z (e.g., the number or layer number of cell capacitors CAP).

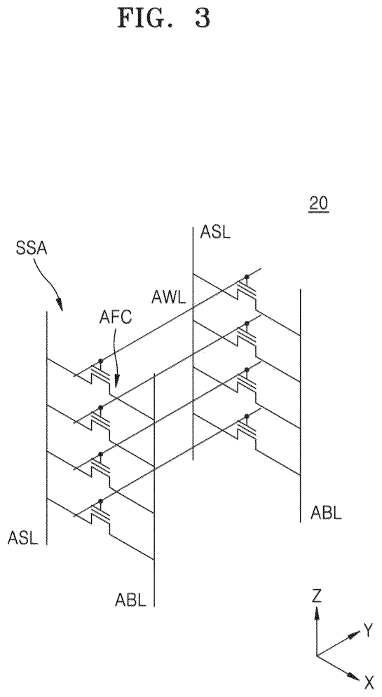

FIG. 3 is a circuit diagram of the antifuse cell array 20 shown in FIG. 1.

Referring to FIG. 3, the antifuse cell array 20 may include a plurality of antifuse sub-cell arrays SAA. The plurality of antifuse sub-cell arrays SAA may be arranged apart from each other in a second lateral direction Y.

The antifuse sub-cell array SAA may include a plurality of antifuse bit lines ABL, a plurality of antifuse word lines AWL, a plurality of antifuse source lines ASL, and a plurality of antifuse cells AFC.

The plurality of antifuse cells AFC may be connected between the plurality of antifuse word lines AWL and the plurality of antifuse bit lines ABL. In some embodiments, each of the plurality of antifuse cells AFC may include a non-volatile memory device of a charge trapping type. For example, the antifuse cells AFC may include a ferroelectric gate, a floating gate type, etc. A gate of the antifuse cell AFC may be connected to the antifuse word line AWL, a source of the antifuse cell AFC may be connected to the antifuse source line ASL, and a drain of the antifuse cell AFC may be connected to the plurality of antifuse bit lines ABL.

In one antifuse sub-cell array SAA, the plurality of antifuse cells AFC may be at locations overlapping each other in a vertical direction Z. In some embodiments, the plurality of antifuse cells AFC may be formed together during at least part of a process of forming the cell transistor TR in the memory cell array 10. In some embodiments, the number (e.g., layer number) of antifuse cells AFC stacked in the vertical direction Z may be equal to the number (e.g., layer number) of cell capacitors CAP stacked in the vertical direction Z. In some embodiments, the number (e.g., layer number) of antifuse cells AFC stacked in the vertical direction Z may be less than the number (e.g., layer number) of cell capacitors CAP stacked in the vertical direction Z.

In some embodiments, each of the plurality of antifuse cells AFC may include a non-volatile memory device of a charge trapping type. The plurality of antifuse cells AFC may have a relatively high first threshold voltage in a programmed state (e.g., after a program operation) and have a second threshold voltage, which is lower than the first threshold voltage, in an unprogrammed state.

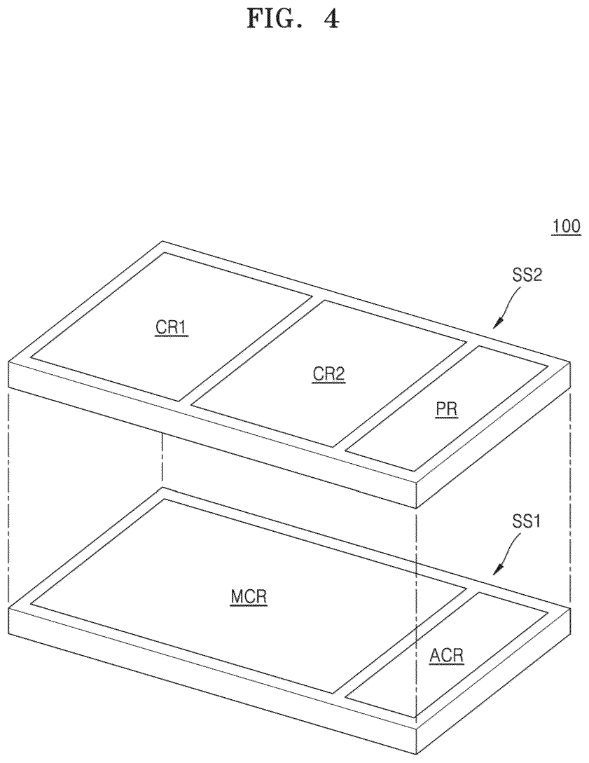

FIG. 4 is a perspective view of a semiconductor memory device 100 according to some embodiments.

Referring to FIG. 4, the semiconductor memory device 100 may have a structure in which a first stack structure SS1 and a second stack structure SS2 are stacked in a vertical direction. For example, the first stack structure SS1 and the second stack structure SS2 may be located at different vertical levels. Although the first stack structure SS1 and the second stack structure SS2 are illustrated separately from each other in FIG. 4 for brevity, the semiconductor memory device 100 may have a structure in which a bottom surface of the second stack structure SS2 is adhered onto a top surface of the first stack structure SS1.

The first stack structure SS1 may include a memory cell region MCR and an antifuse array region ACR. The memory cell region MCR may be a region in which the memory cell array 10 described with reference to FIGS. 1 and 2 is located. For example, bit lines, word lines, and memory cells may be in the memory cell region MCR. The antifuse array region ACR may be a region in which the antifuse cell array 20 described with reference to FIGS. 1 and 3 is located. The antifuse array region ACR may be on one side of the memory cell region MCR. For example, antifuse bit lines, antifuse word lines, and antifuse cells may be located in the antifuse array region ACR.

The second stack structure SS2 may include a first core region CR1, a second core region CR2, and a peripheral circuit region PR. The first core region CR1 and the second core region CR2 may be arranged at locations vertically overlapping the memory cell region MCR and include core circuits electrically connected to the memory cell region MCR. In embodiments, the first core region CR1 may include sense amplifiers, which may be electrically connected to bit lines included in the first stack structure SS1. In embodiments, the second core region CR2 may include sub-word line drivers, which may be electrically connected to the word lines included in the first stack structure SS1.

The peripheral circuit region PR may be located at a location vertically overlapping the antifuse array region ACR. The peripheral circuit region PR may include a control signal generating circuit configured to control a sub-word line driver, a control signal generating circuit configured to control a sense amplifier, and an antifuse cell sensing circuit configured to control an antifuse cell array located in the antifuse array region ACR. In addition, the peripheral circuit region PR may further include a voltage generator configured to provide operating voltages to the sense amplifier, the sub-word line driver, and the antifuse cell sensing circuit.

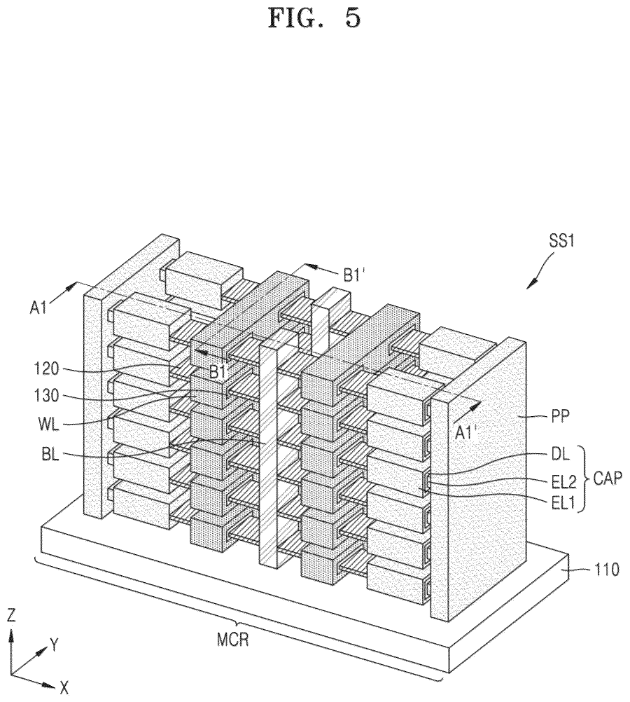

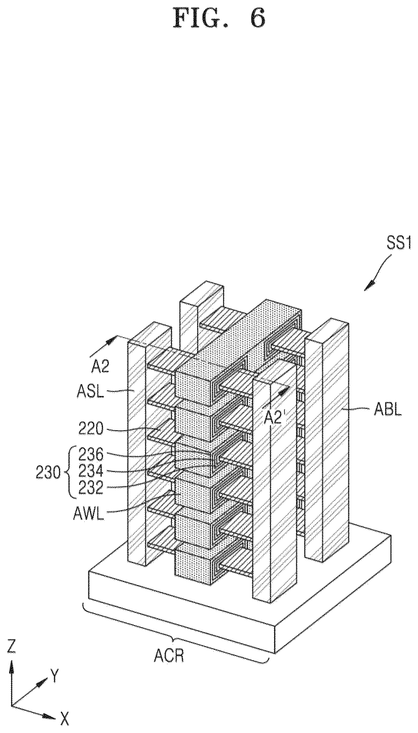

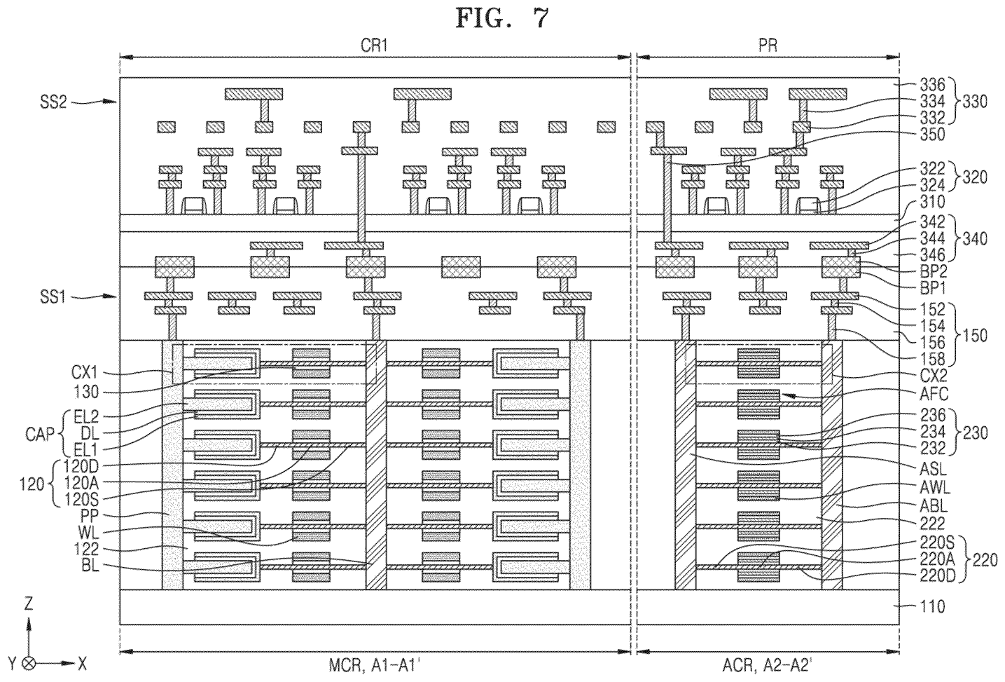

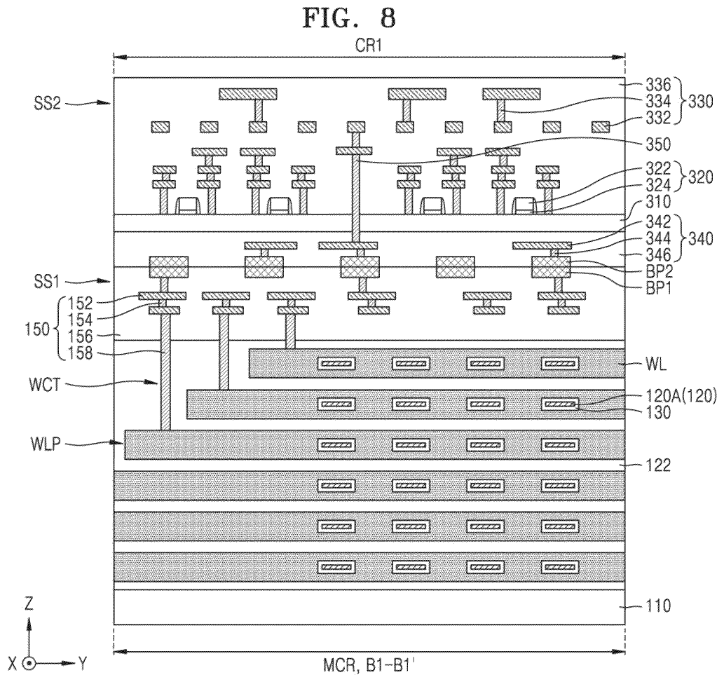

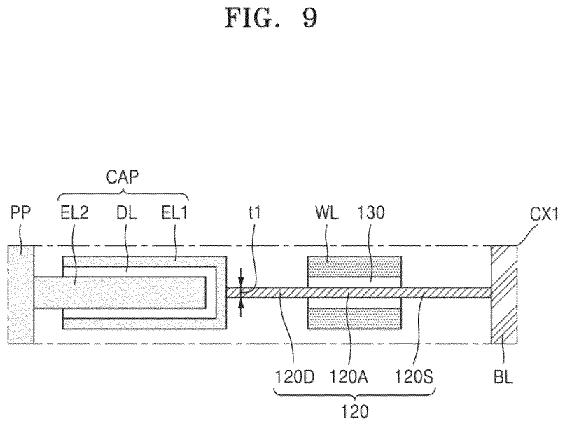

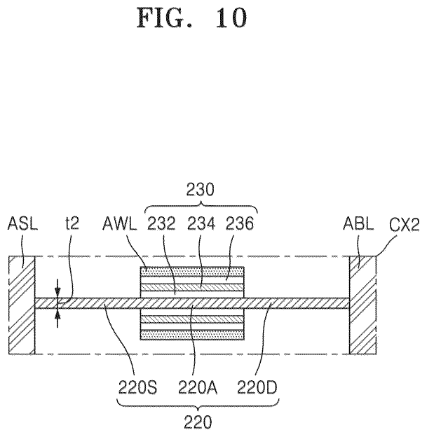

FIG. 5 is a perspective view of the memory cell region MCR of the first stack structure SS1 of FIG. 4. FIG. 6 is a perspective view of the antifuse array region ACR of the first stack structure SS1 of FIG. 4. FIG. 7 shows cross-sectional views taken along lines A1-A1′ of FIGS. 5 and A2-A2′ of FIG. 6, and FIG. 8 is a cross-sectional view taken along line B1-B1′ of FIG. 5. FIG. 9 is an enlarged view of portion CX1 of FIG. 7. FIG. 10 is an enlarged view of portion CX2 of FIG. 7.

Referring to FIGS. 5 to 10, a semiconductor memory device may include a first stack structure SS1 and a second stack structure SS2, and the second stack structure SS2 may be bonded onto the first stack structure SS1 by first and second bonding pads BP1 and BP2. For example, the first stack structure SS1 and the second stack structure SS2 may be bonded through, e.g., hybrid-metal bonding processes such as Cu-to-Cu bonding.

The first stack structure SS1 may include the memory cell region MCR and the antifuse array region ACR. The first stack structure SS1 may include a plurality of first semiconductor patterns 120, a plurality of bit lines BL, a plurality of word lines WL, and a cell capacitor CAP on a first substrate 110 in the memory cell region MCR. The first stack structure SS1 may include a plurality of antifuse bit lines ABL, a plurality of antifuse word lines AWL, and a plurality of antifuse cells AFC on the first substrate 110 in the antifuse array region ACR.

In embodiments, the first substrate 110 may be a semiconductor substrate including, e.g., silicon (Si), germanium (Ge), silicon germanium (SiGe), and/or the like. In embodiments, the first substrate 110 may include a silicon-on-insulator (SOI) substrate and/or a germanium-on-insulator (GeOI) substrate.

In the memory cell region MCR, the plurality of first semiconductor patterns 120 may extend in a first lateral direction X and be apart from each other in a vertical direction Z on the first substrate 110.

In some embodiments, the plurality of first semiconductor patterns 120 may include, for example, an undoped semiconductor material or a doped semiconductor material. In some embodiments, the plurality of first semiconductor patterns 120 may include polysilicon. In some embodiments, the plurality of first semiconductor patterns 120 may include an amorphous metal oxide, a polycrystalline metal oxide, and/or a combination of the amorphous metal oxide and the polycrystalline metal oxide, for example, at least one of indium (In)-gallium (Ga)-based oxide (IGO), In-zinc (Zn)-based oxide (IZO), and/or In—Ga—Zn-based oxide (IGZO). In some other embodiments, the plurality of first semiconductor patterns 120 may include a 2D material semiconductor. For example, the 2D material semiconductor may include MoS₂, WSe₂, semiconductive graphene, semiconductor carbon nanotube, and/or a combination thereof.

In embodiments, each of the plurality of first semiconductor patterns 120 may have a line shape and/or bar shape extending in the first lateral direction X. In embodiments, each of the first semiconductor patterns 120 may include a channel region 120A and a first impurity region 120S and a second impurity region 120D, which are in the first lateral direction X with the channel region 120A therebetween. The first impurity region 120S may be connected to the bit line BL, and the second impurity region 120D may be connected to the cell capacitor CAP. An ohmic metal layer including a metal silicide may be further formed between the first impurity region 120S and the bit line BL and between the second impurity region 120D and the cell capacitor CAP.

The plurality of word lines WL may be on top surfaces and/or bottom surfaces of the plurality of first semiconductor patterns 120, extend in a second lateral direction Y, and be apart from each other in the vertical direction Z. From among the plurality of word lines WL, one word line WL may extend in the second lateral direction Y, while surrounding the plurality of first semiconductor patterns 120 that are apart from each other in the second lateral direction Y. From among the plurality of word lines WL, two word lines WL, which are apart from each other in the vertical direction Z, may overlap each other in the vertical direction Z.

In some embodiments, the plurality of word lines WL may include at least one of a doped semiconductor material (e.g., doped silicon and doped germanium), a conductive metal nitride (e.g., titanium nitride and tantalum nitride), a metal (e.g., tungsten, titanium, and tantalum), and a metal-semiconductor compound (e.g., tungsten silicide, cobalt silicide, and titanium silicide).

In some embodiments, a gate insulation layer 130 may be between the word line WL and the first semiconductor pattern 120. The gate insulation layer 130 may include at least one of a high-k dielectric material having a higher dielectric constant than silicon oxide and/or a ferroelectric material. In some embodiments, the gate insulation layer 130 may include at least one selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), lead scandium tantalum oxide (PbScTaO), and/or the like.

The plurality of bit lines BL may extend in the vertical direction Z on the first substrate 110 and be apart from each other in the second lateral direction Y. The plurality of bit lines BL may include any one of a doped semiconductor material, a conductive metal nitride, a metal, and a metal-semiconductor compound.

The cell capacitor CAP may include a first electrode EL1, a capacitor dielectric layer DL, and a second electrode EL2. First electrodes EL1 may extend in the first lateral direction X and be apart from each other in the vertical direction Z. The first electrode EL1 may have an inner space (not shown) extending in the first lateral direction X, and the inner space of the first electrode EL1 may be filled by the capacitor dielectric layer DL and the second electrode EL2. For example, the first electrode EL1 may have a cup shape rotated by 90°.

The capacitor dielectric layer DL may include at least one of a high-k dielectric material having a higher dielectric constant than silicon oxide and/or a ferroelectric material. In some embodiments, the capacitor dielectric layer DL may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (SrTaBiO), bismuth iron oxide (BiFeO), strontium titanium oxide (SrTiO), yttrium oxide (YO), aluminum oxide (AlO), lead scandium tantalum oxide (PbScTaO), and/or the like.

The second electrode EL2 may fill the inner space of the first electrode EL1, and the capacitor dielectric layer DL may be between the inner space of the first electrode EL1 and the second electrode EL2.

Each of the first electrode EL1 and the second electrode EL2 may include a doped semiconductor material, a conductive metal nitride (e.g., titanium nitride, tantalum nitride, niobium nitride, or tungsten nitride), a metal (e.g., ruthenium, iridium, titanium, or tantalum), or a conductive metal oxide (e.g., iridium oxide or niobium oxide).

A plate electrode PP may be located on one side of the cell capacitor CAP and extend in the vertical direction Z and the second lateral direction Y. The second electrode EL2 of the cell capacitor CAP may be electrically connected to the plate electrode PP. For example, the plate electrode PP may be connected in common to a plurality of second electrodes EL2, which are apart from each other in the vertical direction Z, and a plurality of second electrodes EL2, which are apart from each other in the second lateral direction Y.

A mold insulating layer 122 may be located between two first semiconductor patterns 120, which are adjacent to each other to be apart from each other in the vertical direction Z, between two word lines WL, which are adjacent to each other to be apart from each other in the vertical direction Z, and between two first electrodes EL1, which are adjacent to each other to be apart from each other in the vertical direction Z. In addition, the mold insulating layer 122 may be between two bit lines BL, which are apart from each other in the second lateral direction Y.

The mold insulating layer 122 may include an insulator material, such as silicon oxide, silicon oxynitride, silicon nitride, carbon-containing silicon oxide, carbon-containing silicon oxynitride, carbon-containing silicon nitride, a combination thereof, and/or the like. In some embodiments, the mold insulating layer 122 may include a plurality of insulating layers. Herein, according to a manufacturing process employed to form a three-dimensional (3D) structure, insulating material layers formed between the plurality of bit lines BL, between the plurality of word lines WL, between the plurality of first semiconductor patterns 120, and between a plurality of cell capacitors CAP may be collectively referred to as the mold insulating layer 122.

In the antifuse array region ACR, the plurality of antifuse cells AFC may be spaced apart from each other in the vertical direction Z on the first substrate 110. Each of the antifuse cells AFC may include a second semiconductor pattern 220 and an antifuse gate insulating layer 230 surrounding the second semiconductor pattern 220 and further include an antifuse word line AWL. The antifuse cell AFC may be a non-volatile memory device of a charge trapping type, have a first threshold voltage in an unprogrammed state, and have a second threshold voltage different from the first threshold voltage (e.g., a second threshold voltage lower than or equal to the first threshold voltage) in a programmed state. In the some embodiments, the antifuse cell AFC may constitute an antifuse device array that is stacked three-dimensionally.

A plurality of second semiconductor patterns 220 may extend in the first lateral direction X on the first substrate 110 and be spaced apart from each other in the vertical direction Z. In some embodiments, the plurality of second semiconductor patterns 220 may include, for example, an undoped semiconductor material or a doped semiconductor material. In some embodiments, the plurality of second semiconductor patterns 220 may include polysilicon. In some embodiments, the plurality of second semiconductor patterns 220 may include an amorphous metal oxide, a polycrystalline metal oxide, or a combination of the amorphous metal oxide and the polycrystalline metal oxide, for example, at least one of InGaO, InZnO, and InGaZnO. In some other embodiments, the plurality of second semiconductor patterns 220 may include a 2D material semiconductor. For example, the 2D material semiconductor may include MoS₂, WSe₂, semiconductive graphene, semiconductive carbon nanotube, a combination thereof, and/or the like.

In some embodiments, each of the plurality of second semiconductor patterns 220 may have a line shape or bar shape extending in the first lateral direction X. In some embodiments, each of the second semiconductor patterns 220 may include a channel region 220A and a first impurity region 220S and a second impurity region 220D, which are spaced apart from each other with the channel region 220A therebetween in the first lateral direction X. The first impurity region 220S may be connected to the antifuse source line ASL and correspond to a source, and the second impurity region 220D may be connected to the antifuse bit line ABL and correspond to a drain. An ohmic metal layer including a metal silicide may be further formed between the first impurity region 220S and the antifuse source line ASL and between the second impurity region 220D and the antifuse bit line ABL.

In some embodiments, the plurality of second semiconductor patterns 220 may be formed simultaneously during the process of forming the plurality of first semiconductor patterns 120. For example, a semiconductor layer and a sacrificial layer may be alternately stacked on the first substrate 110. Subsequently, by removing portions of the semiconductor layer, the plurality of first semiconductor patterns 120 may be formed in the memory cell region MCR, and the plurality of second semiconductor patterns 220 may be formed in the antifuse array region ACR.

In some embodiments, a thickness t2 of each of the plurality of second semiconductor patterns 220 in the vertical direction Z may be the same as and/or substantially similar to a thickness t1 of each of the plurality of first semiconductor patterns 120 in the vertical direction Z. In addition, the plurality of second semiconductor patterns 220 may be at the same vertical level as the plurality of first semiconductor patterns 120, and the number of second semiconductor patterns 220 arranged in the vertical direction Z may be equal to the number of first semiconductor patterns 120 arranged in the vertical direction Z.

The plurality of antifuse word lines AWL may be on top surfaces and bottom surfaces of the plurality of second semiconductor patterns 220, extend in the second lateral direction Y, and be apart from each other in the vertical direction Z. From among the plurality of antifuse word lines AWL, one antifuse word line AWL may extend in the second lateral direction Y, while surrounding the plurality of second semiconductor patterns 220 that are apart from each other in the second lateral direction Y.

In some embodiments, the plurality of antifuse word lines AWL may include at least one of a doped semiconductor material (e.g., doped silicon and doped germanium), a conductive metal nitride (e.g., titanium nitride and tantalum nitride), a metal (e.g., tungsten, titanium, and tantalum), and a metal-semiconductor compound (e.g., tungsten silicide, cobalt silicide, and titanium silicide).

In some embodiments, the antifuse gate insulating layer 230 may be between the antifuse word line AWL and the second semiconductor pattern 220. The antifuse gate insulating layer 230 may include a tunneling dielectric layer 232, a charge storage layer 234, and a blocking dielectric layer 236. As shown in FIG. 10, the tunneling dielectric layer 232, the charge storage layer 234, and the blocking dielectric layer 236 may be sequentially located on the top surface, the bottom surface, and both sidewalls of the second semiconductor pattern 220.

In some embodiments, the tunneling dielectric layer 232 may include an insulating material, such as silicon oxide, hafnium oxide, aluminum oxide, zirconium oxide, and/or tantalum oxide.

In some embodiments, the charge storage layer 234 may be a region in which electrons passing through the tunneling dielectric layer 232 from the channel region 220A of the second semiconductor pattern 220 may be stored. In some embodiments, the charge storage layer 234 may include silicon nitride, boron nitride, silicon boron nitride, and/or doped polysilicon as a base material. The charge storage layer 234 may include, e.g., a ferroelectric material configured to maintain polarization. The blocking dielectric layer 236 may include an insulator such as silicon oxide, silicon nitride, or a metal oxide having higher dielectric constant than silicon oxide. The metal oxide may include, for example, hafnium oxide, aluminum oxide, zirconium oxide, tantalum oxide, a combination thereof, and/or the like.

In some embodiments, the charge storage layer 234 may include a ferroelectric dielectric material. In these cases, the charge storage layer 234 may include a metal oxide having ferroelectric material characteristics. For example, the charge storage layer 234 may include a ferroelectric material capable of storing data due to hysteresis behavior caused by a voltage applied to the charge storage layer 234. In embodiments, the charge storage layer 234 may include at least one of hafnium oxide, zirconium oxide, and/or hafnium zirconium oxide and have a ferroelectric crystalline phase.

The plurality of antifuse bit lines ABL may extend in the vertical direction Z on the first substrate 110 and be apart from each other in the second lateral direction Y. The plurality of antifuse bit lines ABL may include, e.g., a doped semiconductor material, a conductive metal nitride, a metal, and a metal-semiconductor compound. The plurality of antifuse bit lines ABL may be electrically connected to the second impurity region 220D of the second semiconductor pattern 220.

The plurality of antifuse source lines ASL may extend in the vertical direction Z on the first substrate 110 and be apart from each other in the second lateral direction Y. The plurality of antifuse source lines ASL may include a doped semiconductor material, a conductive metal nitride, a metal, and a metal-semiconductor compound. The plurality of antifuse source lines ASL may be electrically connected to the first impurity region 220S of the second semiconductor pattern 220.

In some embodiments, the plurality of antifuse bit lines ABL and the plurality of antifuse source lines ASL may be simultaneously formed during the process of forming the plurality of bit lines BL. For example, by using a one-time mask patterning process, a bit line opening may be formed in the memory cell region MCR, and an antifuse bit line opening and an antifuse source line opening may be formed in the antifuse array region ACR. Subsequently, the bit line opening, the antifuse bit line opening, and the antifuse source line opening may be filled by a conductive material, and thus, the plurality of bit lines BL may be formed in the memory cell region MCR, and the plurality of antifuse bit lines ABL and the plurality of antifuse source lines ASL may be formed in the antifuse array region ACR.

A mold insulating layer 222 may be located between two second semiconductor patterns 220, which are adjacent to each other to be apart from each other in the vertical direction Z, and between two antifuse word lines AWL, which are adjacent to each other to be apart from each other in the vertical direction Z. In addition, the mold insulating layer 222 may be between two antifuse bit lines ABL, which are apart from each other in the second lateral direction Y, and between two antifuse source lines ASL, which are apart from each other in the second lateral direction Y.

In some embodiments, the mold insulating layer 222 may include an insulating material, such as silicon oxide, silicon oxynitride, silicon nitride, carbon-containing silicon oxide, carbon-containing silicon oxynitride, carbon-containing silicon nitride, a combination thereof, and/or the like. In some embodiments, the mold insulating layer 222 may include a plurality of insulating layers. Herein, according to a manufacturing process employed to form a 3D structure, insulating material layers formed between the plurality of antifuse bit lines ABL, between the plurality of antifuse word lines AWL, between the plurality of second semiconductor patterns 220, and between the plurality of antifuse source lines ASL may be collectively referred to as the mold insulating layer 222.

An upper wiring structure 150 may be on the memory cell region MCR and the antifuse array region ACR. The upper wiring structure 150 may include a wiring layer 152, a via 154, and an insulating layer 156. The upper wiring structure 150 may further include a contact 158 electrically connected to the bit line BL, the word line WL, and the plate electrode PP. In addition, a first bonding pad BP1 may be formed on the upper wiring structure 150 on the same plane as an uppermost surface of the insulating layer 156.

The second stack structure SS2 may include a second substrate 310, a peripheral circuit transistor 320 on the second substrate 310, a front wiring structure 330 covering the peripheral circuit transistor 320 on a top surface of the second substrate 310, and a rear wiring structure 340 on a bottom surface of the second substrate 310. The front wiring structure 330 may include a wiring layer 332, a via 334, and an insulating layer 336, and the rear wiring structure 340 may include a wiring layer 342, a via 344, and an insulating layer 346.

The rear wiring structure 340 may include a second bonding pad BP2 located on the same plane as a bottom surface of the insulating layer 346. Because the first bonding pad BP1 is connected to the second bonding pad BP2, the first stack structure SS1 may be bonded to the second stack structure SS2. In some embodiments, the first stack structure SS1 may be adhered to the second stack structure SS2 by using a copper-oxide hybrid bonding method. In embodiments, the first bonding pad BP1 and the second bonding pad BP2 may include copper or a copper alloy. An interface between the insulating layer 156 of the upper wiring structure 150 and the insulating layer 346 of the rear wiring structure 340 may extend planar and on the same plane as an interface between the first bonding pad BP1 and the second bonding pad BP2.

In some embodiments, the peripheral circuit transistor 320 may include a gate electrode 322 and a gate insulation layer 324, which are on an active region of the second substrate 310. In embodiments, the peripheral circuit transistor 320 in the first core region CR1 may include sense amplifiers, which may be electrically connected to bit lines BL included in the first stack structure SS1. The peripheral circuit transistor 320 in the second core region (refer to CR2 in FIG. 4) may include sub-word line drivers, which may be electrically connected to word lines WL included in the first stack structure SS1.

In some embodiments, the second stack structure SS2 may further include a through via 350 passing through the second substrate 310, and the wiring layer 332 included in the front wiring structure 330 may be electrically connected to the wiring layer 332 included in the rear wiring structure 340 by the through via 350. The wiring layer 332 included in the rear wiring structure 340 may be electrically connected to the wiring layer 332 included in the front wiring structure 330 through the first bonding pad BP1 and the second bonding pad BP2.

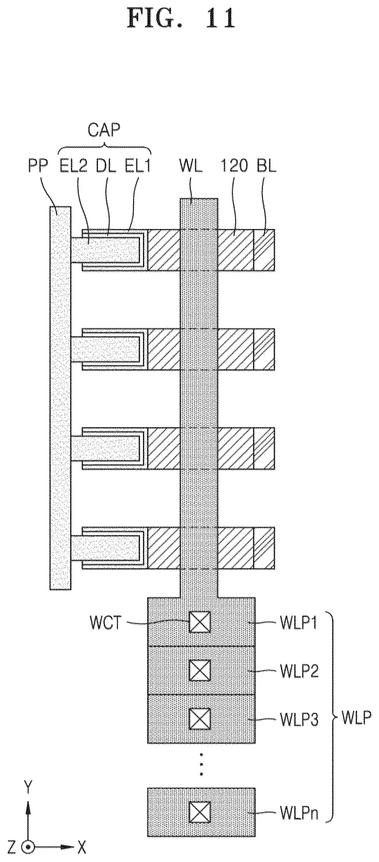

FIG. 11 is a layout diagram of a semiconductor memory device 100 according to embodiments.

Referring to FIG. 11 together with FIG. 8, a word line WL may extend in a second lateral direction Y to intersect a first lateral direction X, which is a direction in which a first semiconductor pattern 120 extends. A word line pad WLP may be at an end portion of the word line WL. As shown in FIG. 11, a plurality of word line pads WLP may be sequentially arranged in the second lateral direction Y. As shown in FIG. 8, the plurality of word line pads WLP may be arranged in a staircase form in the second lateral direction Y.

In some embodiments, a first word line pad WLP1 connected to an uppermost word line WL, a second word line pad WLP2 connected to a word line WL located under the uppermost word line WL, a third word line pad WLP3 connected to a word line WL located under two uppermost word lines WL, . . . , and an n-th word line pad WLPn connected to an n-th word line WL may be sequentially arranged in the second lateral direction Y from top to bottom.

A word line contact WCT may be on a top surface of each of the word line pads WLP, and the word line WL may be electrically connected to an upper wiring structure 150 by the word line contact WCT.

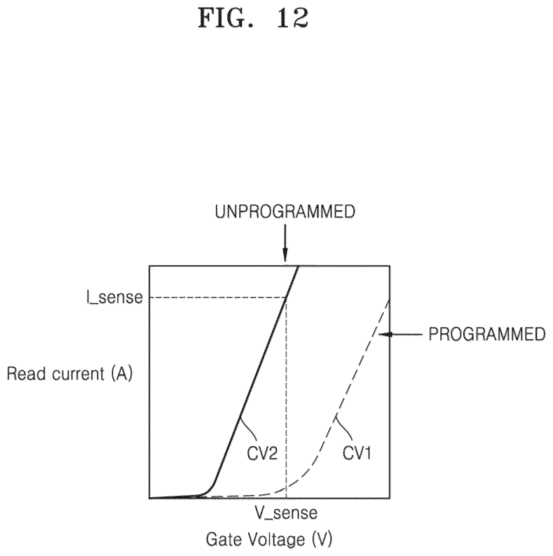

FIG. 12 is a schematic view of a voltage-current curve of an antifuse cell included in a semiconductor memory device according to embodiments.

Referring to FIG. 12, a first curve CV1 of the antifuse cell represents a read current curve according to a gate voltage in a programmed state, and the antifuse cell in the programmed state may have a first threshold voltage. For example, the first threshold voltage may have a relatively high value, which is higher than a sensing voltage V_sense.

In some embodiments, a program operation may be implemented in a charge trapping manner. For example, when a relatively high program voltage is applied to an antifuse word line AWL, electrons from the second semiconductor pattern (refer to 220 in FIG. 8) may be stored in the charge storage layer 234 by tunneling the tunneling dielectric layer 232 by using, for example, a Fowler-Nordheim (FN) tunneling method.

In a programmed state, when the sensing voltage V_sense is applied to the antifuse cell, a relatively negligible amount of current (or current close to 0) may flow. In this case, the antifuse cell may be considered to be turned off.

A second curve CV2 of the antifuse cell represents a read current curve according to a gate voltage in an unprogrammed state, and the antifuse cell in the unprogrammed state may have a second threshold voltage. For example, the second threshold voltage may have a relatively low voltage, be lower than the first threshold voltage, and be lower than the sensing voltage V_sense.

In some embodiments, the unprogrammed state may be implemented by an erase operation. For example, when a relatively low erase voltage is applied to an antifuse word line AWL (e.g., when a relatively high source voltage is applied to an antifuse source line ASL and a gate voltage of 0 V is applied to the antifuse word line AWL), electrons may be migrated from the charge storage layer 234 into the second semiconductor pattern 220 by tunneling the tunneling dielectric layer 232 by using, for example, an FN tunneling method.

In the unprogrammed state, when the sensing voltage V_sense is applied to the antifuse cell, a relatively large amount of sensing current I_sense may flow. In this case, the antifuse cell may be considered to be turned on.

In some embodiments, when a defect occurs in some of memory cells, a method of replacing a defective memory cell with a redundancy cell that is previously manufactured in a memory device may be used. If a defective cell exists in a portion of a memory cell, the antifuse cell may be turned on through an erase operation, and thus, the defective memory cell may be replaced with the redundancy cell.

According to the semiconductor memory device 100 described with reference to FIGS. 1 to 12, the first stack structure SS1 may include an antifuse array region ACR, which is at a location vertically overlapping the peripheral circuit region PR included in the second stack structure SS2. Furthermore, an antifuse cell AFC in the antifuse array region ACR may be driven in a charge trapping manner and may be formed simultaneously by using at least some operations included in a process of manufacturing memory cells included in the memory cell region MCR of the first stack structure SS1. Accordingly, the spatial efficiency of a chip including a 3D semiconductor memory device may improve.

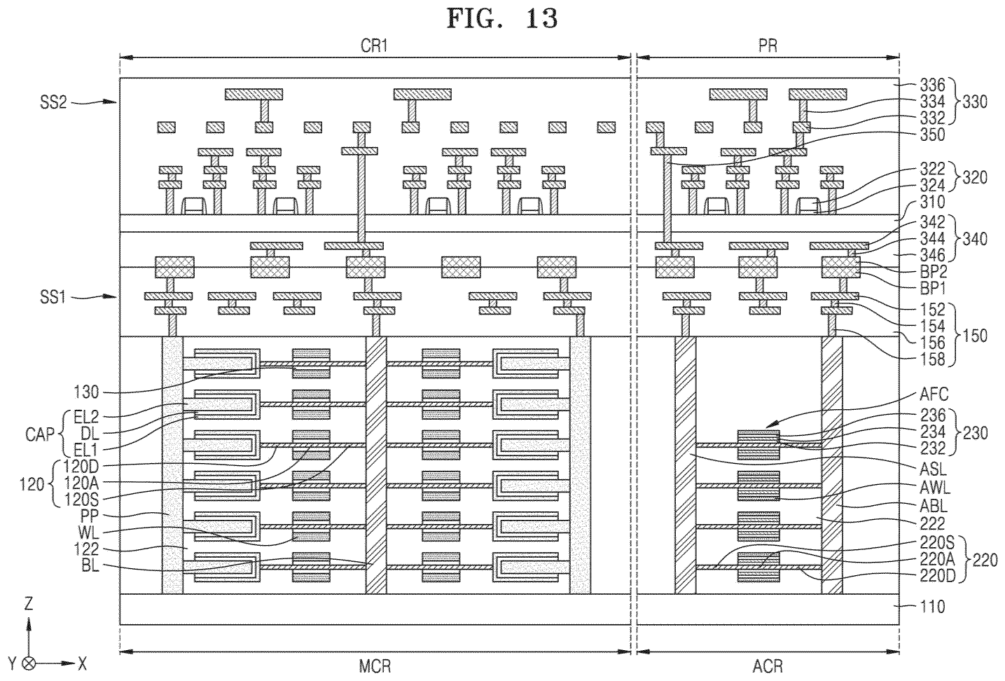

FIG. 13 is a cross-sectional view of a semiconductor memory device according to some embodiments.

Referring to FIG. 13, the number of antifuse cells AFC arranged in a vertical direction Z or the number of second semiconductor patterns 220 arranged in the vertical direction Z in an antifuse array region ACR may be less than the number of first semiconductor patterns 120 arranged in the vertical direction Z in a memory cell region MCR.

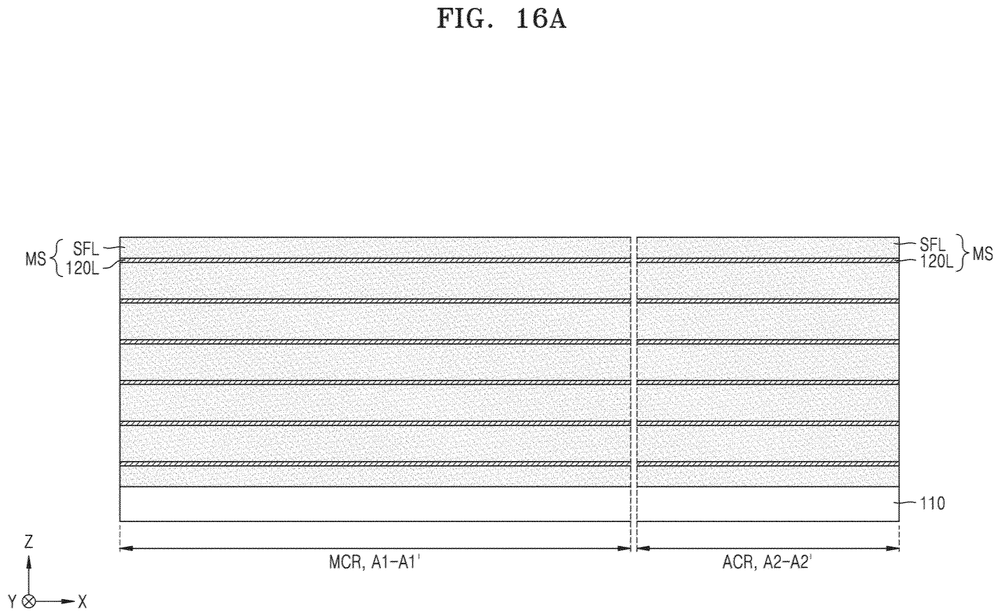

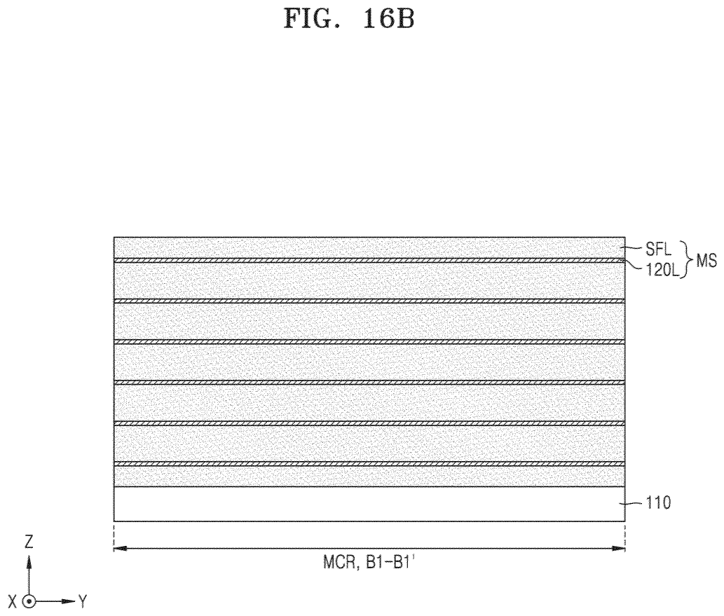

In some embodiments, a plurality of second semiconductor patterns 220 may be formed simultaneously during the process of forming a plurality of first semiconductor patterns 120. For example, a semiconductor layer (refer to 120L in FIG. 16A) and a sacrificial layer (refer to SFL in FIG. 16A) may be alternately stacked on the first substrate 110. Subsequently, by removing portions of the semiconductor layer 120L, a plurality of first semiconductor patterns 120 may be formed in the memory cell region MCR, and a plurality of second semiconductor patterns 220 may be formed in the antifuse array region ACR. Subsequently, in the antifuse array region ACR, from among the plurality of second semiconductor patterns 220, the second semiconductor pattern 220 located at an upper side may be removed, and only a portion of the second semiconductor pattern 220 located at a lower side may be left.

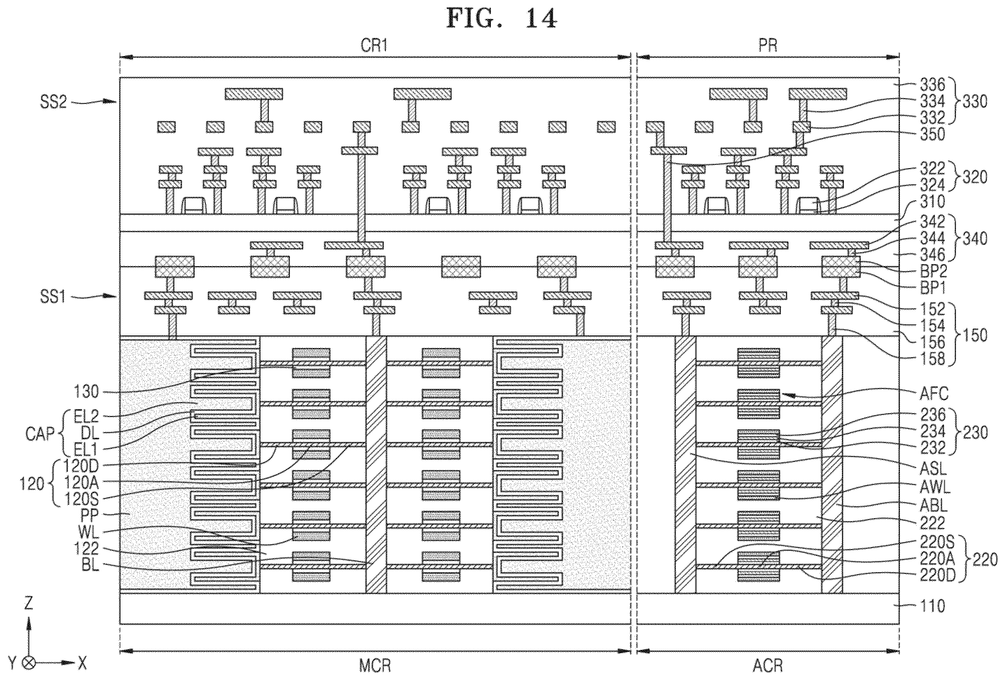

FIG. 14 is a cross-sectional view of a semiconductor memory device according to some embodiments.

Referring to FIG. 14, a cell capacitor CAP may include a first electrode EL1, a capacitor dielectric layer DL, and a second electrode EL2. The first electrode EL1 may have a cut shape and extend in a first lateral direction X. The capacitor dielectric layer DL may be conformally on an inner space and an outer surface of the first electrode EL1. The second electrode EL2 may fill the inner space of the first electrode EL1. The second electrode EL2 may be integrally formed with a plate electrode PP.

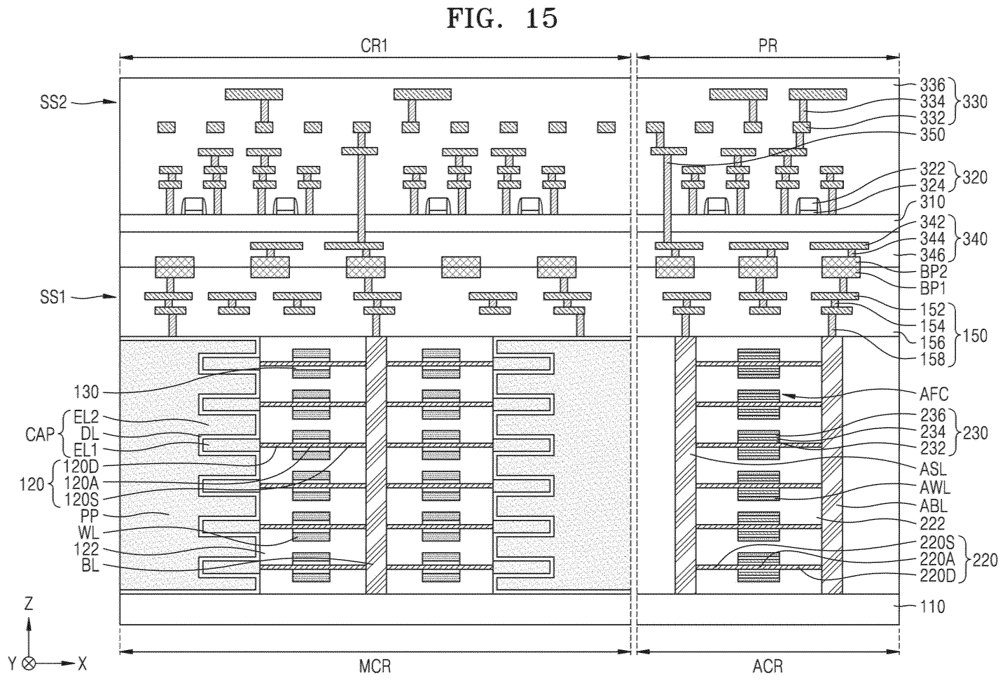

FIG. 15 is a cross-sectional view of a semiconductor memory device according to some embodiments.

Referring to FIG. 15, a cell capacitor CAP may include a first electrode EL1 of a pillar or bar type extending in a first lateral direction X, a capacitor dielectric layer DL conformally located on an outer surface of the first electrode EL1, and a second electrode EL2 surrounding the first electrode EL1 on the capacitor dielectric layer DL. In some embodiments, the second electrode EL2 may be integrally formed with a plate electrode PP. In some other embodiments, the second electrode EL2 may include a thin layer conformally surrounding the capacitor dielectric layer DL, and the plate electrode PP may cover the second electrode EL2.

FIGS. 16A, 16B, 17A, 17B, 18A, 18B, 19A, 19B, 20 to 22, 23A, 23B, 24A, and 24B are schematic views of a method of manufacturing a semiconductor memory device, according to some embodiments.

Referring to FIGS. 16A and 16B, a sacrificial mold layer SFL and a semiconductor layer 120L may be alternately and sequentially formed on a first substrate 110 to form a mold stack MS. The mold stack MS may be in a memory cell region MCR and an antifuse array region ACR.

In some embodiments, the sacrificial mold layer SFL and the semiconductor layer 120L may be formed using materials having an etch selectivity with respect to each other. For example, each of the sacrificial mold layer SFL and the semiconductor layer 120L may include a single crystalline layer of a Group-IV semiconductor, a Group IV-IV compound semiconductor, or a Group III-V compound semiconductor, and the sacrificial mold layer SFL and the semiconductor layer 120L may include different materials from each other. In an example, the sacrificial mold layer SFL may include SiGe, and the semiconductor layer 120L may include single crystalline silicon. Each of the sacrificial mold layer SFL and the semiconductor layer 120L may have a thickness of several tens of nm.

In some embodiments, the sacrificial mold layer SFL and the semiconductor layer 120L may be formed by using an epitaxy process. For example, the epitaxy process may include a vapor-phase epitaxy (VPE) process, a chemical vapor deposition (CVD) process (e.g., an ultra-high vacuum CVD (UHV-CVD) process), a molecular beam epitaxy process, a combination thereof, and/or the like. In the epitaxy process, a liquid or gaseous precursor may be used as a precursor required for forming the sacrificial mold layer SFL and the semiconductor layer 120L.

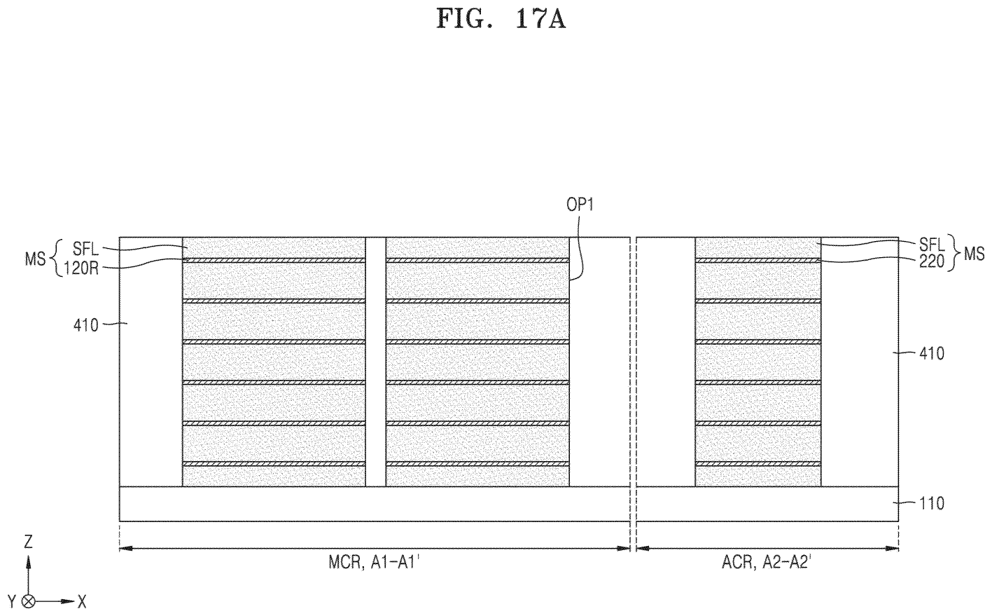

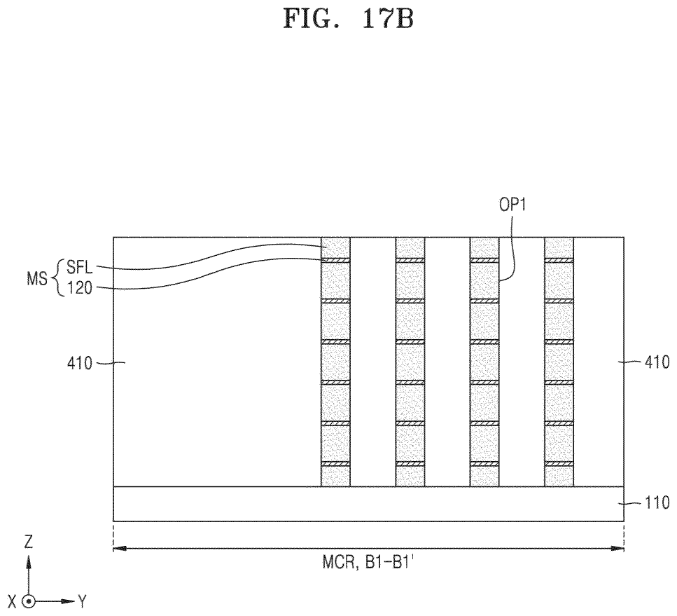

Referring to FIGS. 17A and 17B, a mask pattern (not shown) may be formed on the mold stack MS, and a portion of the mold stack MS may be removed by using the mask pattern as an etch mask to form a first opening OP1. Thereafter, an insulating layer 410 may be formed inside the first opening OP1.

In some embodiments, by forming the first opening OP1, a plurality of first semiconductor patterns 120 may be formed from the semiconductor layer 120L in the memory cell region MCR, and a plurality of second semiconductor patterns 220 may be formed from the semiconductor layer 120L in the antifuse array region ACR. Herein, the plurality of first semiconductor patterns 120 may be formed by patterning portions of the semiconductor layer 120L located in the memory cell region MCR, and the plurality of second semiconductor patterns 220 may be formed by patterning portions of the semiconductor layer 120L located in the antifuse array region ACR.

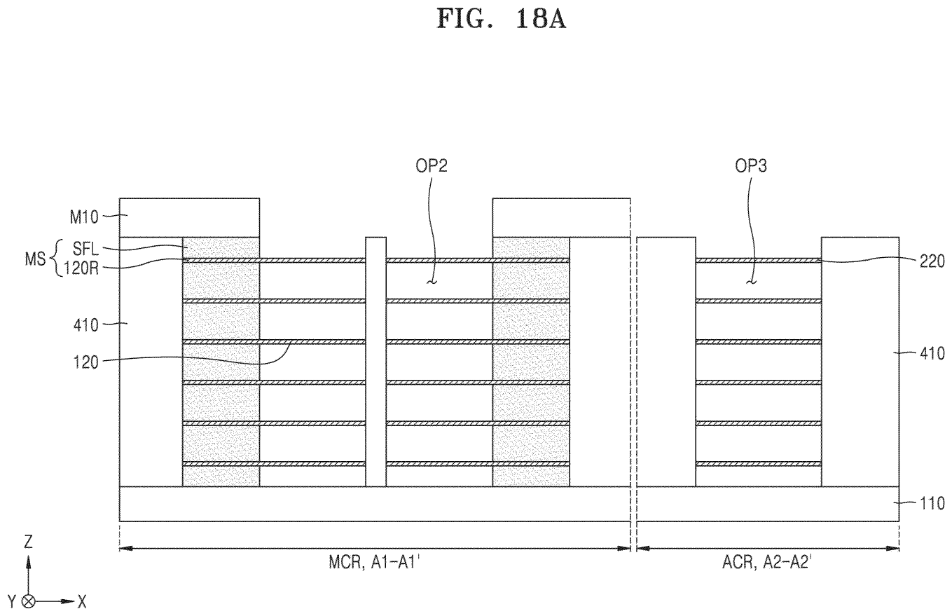

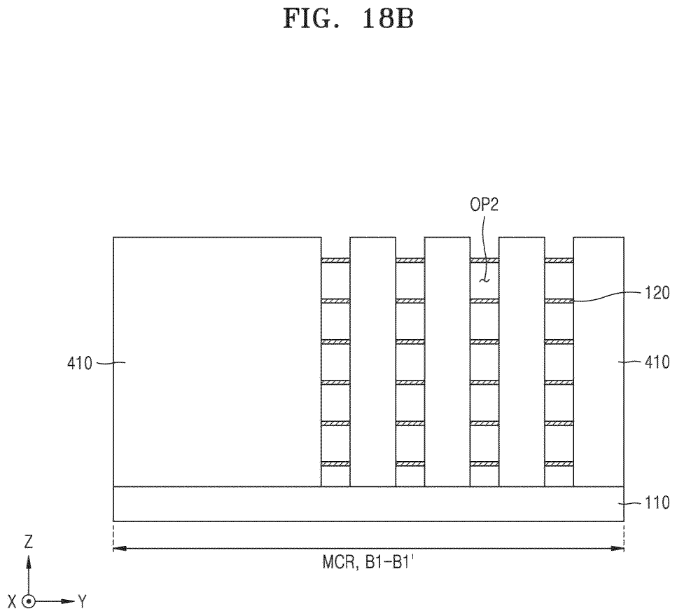

Referring to FIGS. 18A and 18B, the sacrificial mold layer SFL may be removed, and thus, a second opening OP2 may be formed between the plurality of first semiconductor patterns 120, and a third opening OP3 may be formed between the plurality of second semiconductor patterns 220.

In some embodiments, as shown in FIG. 18A, a mask pattern M10 may be formed on the mold stack MS of the memory cell region MCR, a portion of the sacrificial mold layer SFL, which is not covered by the mask pattern M10, may be removed, and portions of the sacrificial mold layer SFL, which are at locations vertically overlapping the mask pattern M10, may remain without being removed. Here, a portion of the first semiconductor pattern 120, which is covered by the sacrificial mold layer SFL, may be referred to as a residual pattern 120R. The mask pattern M10 may be on a structure in which the residual pattern 120R and the sacrificial mold layer SFL are alternately stacked.

In some embodiments, the process of removing the sacrificial mold layer SFL may include a wet etching process and/or a pullback process. For example, the process of removing the sacrificial mold layer SFL may include an etching process using an etch selectivity between the sacrificial mold layer SFL and the semiconductor layer 120L. For instance, in the wet etching process or the pullback process, the plurality of first semiconductor patterns 120 and the plurality of second semiconductor patterns 220 may be etched at a relatively low etch rate, and the sacrificial mold layer SFL may be etched at a relatively high etch rate.

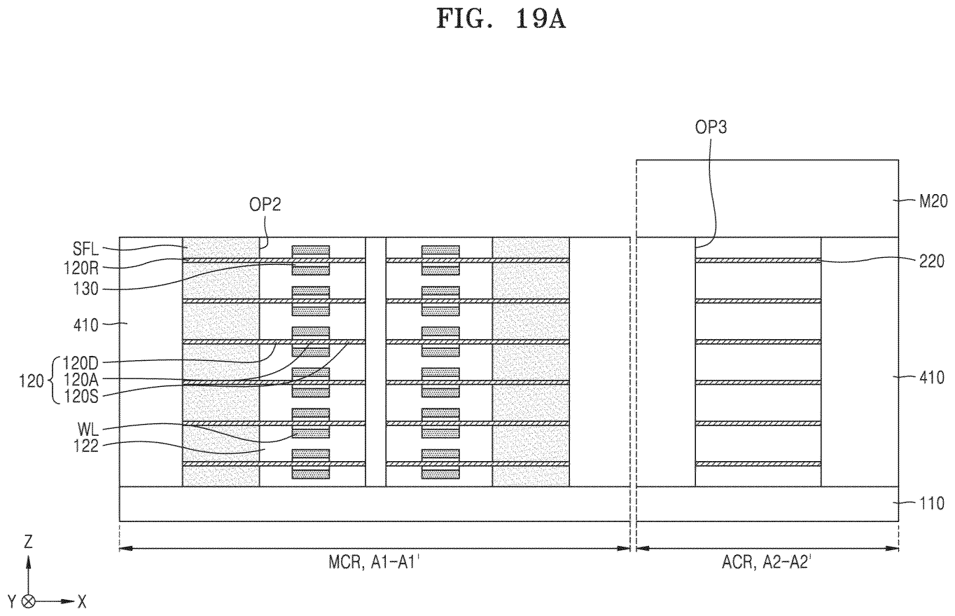

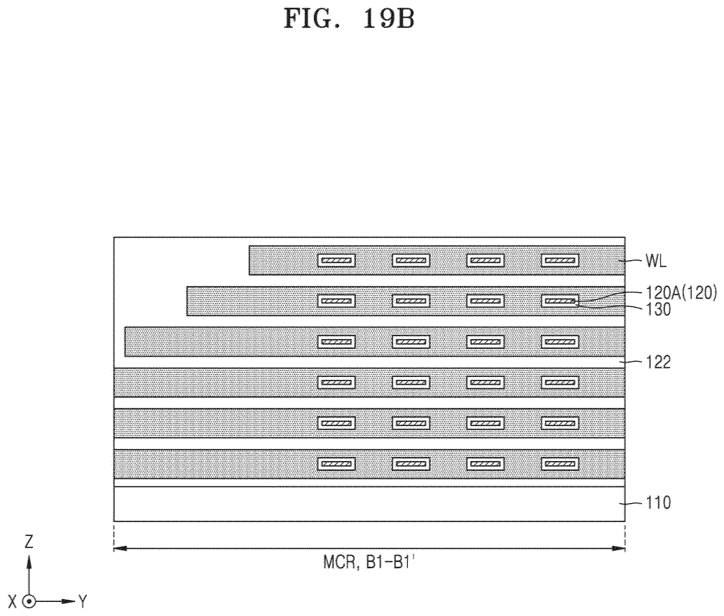

Referring to FIGS. 19A and 19B, a protective layer M20 may be formed to fill the third opening OP3 between the plurality of second semiconductor patterns 220 in the antifuse array region ACR. The protective layer M20 may be formed by using silicon oxide, silicon nitride, a low-k dielectric material, a spin-on-hardmask (SOH), and/or an amorphous carbon layer (ACL).

In the memory cell region MCR, a gate insulation layer 130 and a word line WL may be sequentially formed on a top surface, a side surface, and a bottom surface of each of the plurality of first semiconductor patterns 120 inside the second opening OP2. For example, the gate insulation layer 130 may be conformally located to surround the plurality of first semiconductor patterns 120, and the word line WL may extend in a second lateral direction Y, while surrounding the plurality of first semiconductor patterns 120 on the gate insulation layer 130. In some embodiments, the gate insulation layer 130 and/or the word lines WL may be formed by using an epitaxial process and/or an electrochemical method.

Additionally, as shown in FIG. 19A, portions of the gate insulating layer 130 and the word line WL on both end portions (e.g., both end portions in the first lateral direction X) of each of the plurality of first semiconductor patterns 120 inside the second opening OP2 may be removed. In other embodiments, after a protective layer (not shown) is first formed to cover both end portions of each of the plurality of first semiconductor patterns 120 inside the second opening OP2, the gate insulation layer 130 and the word line WL may be formed to surround a central portion of each of the plurality of first semiconductor patterns 120, and the protective layer may be then removed. Thus, both end portions of each of the plurality of first semiconductor patterns 120 may be exposed again without being covered by the gate insulation layer 130 and the word line WL.

Subsequently, a mold insulating layer 122 may be formed to fill the inside of the second opening OP2. In some embodiments, the mold insulating layer 122 may be between two word lines WL, which are adjacent to each other in a vertical direction Z, and between end portions of two first semiconductor patterns 120, which are adjacent to each other in the vertical direction Z.

In some embodiments, a portion of the word line WL may be removed to form a word line pad WLP. The word line pad WLP may be arranged in a staircase form. For example, the word line pad WLP connected to one word line WL may be apart from the word line pad WLP connected to another word line WL located under the one word line WL in the second lateral direction Y.

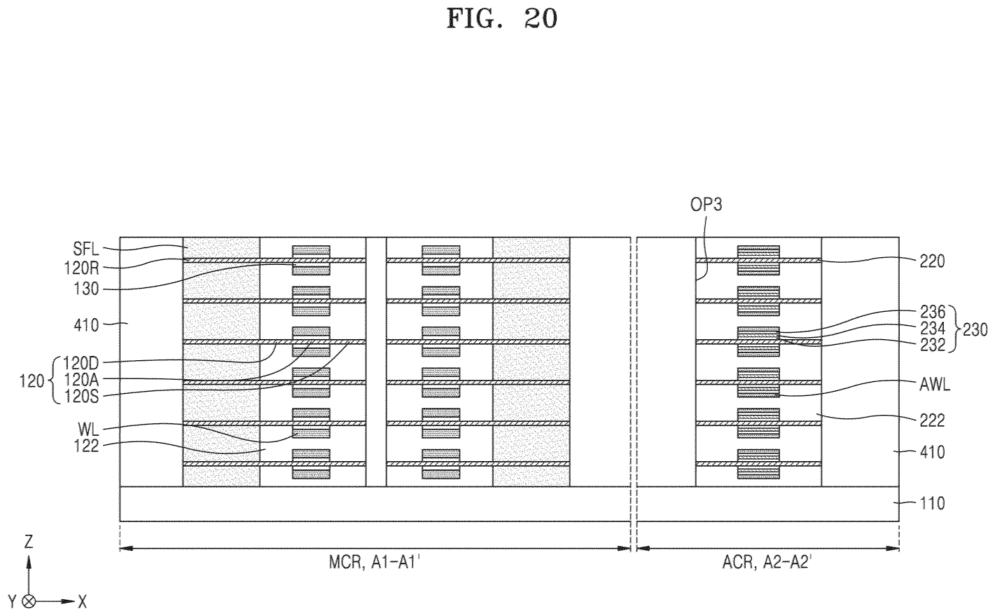

Referring to FIG. 20, in the antifuse array region ACR, a protective layer (refer to M20 in FIG. 19A) may be removed, and the plurality of second semiconductor patterns 220 and the third opening OP3 may be exposed again. Subsequently, in the antifuse array region ACR, an antifuse gate insulating layer 230 and an antifuse word line AWL may be sequentially formed on a top surface, a side surface, and a bottom surface of each of the plurality of second semiconductor patterns 220 inside the third opening OP3. For example, the antifuse gate insulating layer 230 may be conformally located to surround the plurality of second semiconductor patterns 220, and the antifuse word line AWL may surround the plurality of second semiconductor patterns 220 and extend in the second lateral direction Y on the antifuse gate insulating layer 230. In some embodiments, the antifuse gate insulating layer 230 and the antifuse word line AWL may be formed by using an epitaxial process and/or an electrochemical method.

In some embodiments, as shown in FIG. 20, portions of the antifuse gate insulating layer 230 and the antifuse word line AWL on both end portions (e.g., both end portions in the first lateral direction X) of each of the plurality of second semiconductor patterns 220 may be removed. In other embodiments, after a protective layer (not shown) is first formed to cover both end portions of each of the plurality of second semiconductor patterns 220, an antifuse gate insulating layer 230 and an antifuse word line AWL may be formed to surround a central portion of each of the plurality of second semiconductor patterns 220, and the protective layer may be then removed. Thus, both end portions of each of the plurality of second semiconductor patterns 220 may be exposed again without being covered by the antifuse gate insulating layer 230 and the antifuse word line AWL.

Thereafter, a mold insulating layer 222 may be formed to fill the inside of the third opening OP3. In some embodiments, the mold insulating layer 222 may be between two antifuse word lines AWL, which are adjacent to each other in the vertical direction Z, and between two second semiconductor patterns 220, which are adjacent to each other in the vertical direction Z.

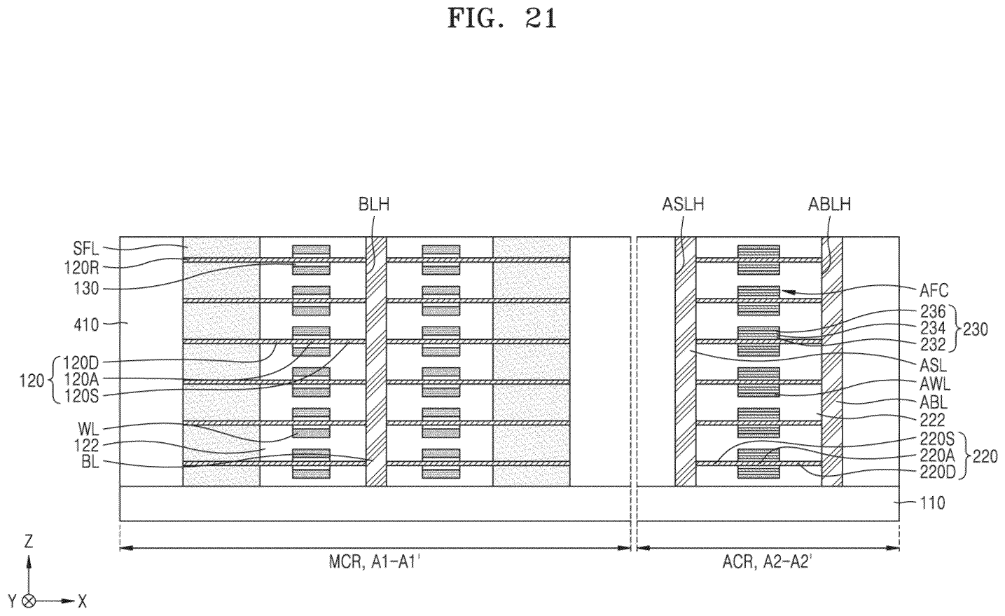

Referring to FIG. 21, in the memory cell region MCR, a portion of the insulating layer 410 may be removed to form a bit line opening BLH, and a bit line BL may be formed inside the bit line opening BLH.

In embodiments, as shown in FIG. 21, two first semiconductor patterns 120 may be apart from each other with the bit line BL therebetween in the first lateral direction X. A first sidewall of one bit line BL may be in contact with a first impurity region 120S of one first semiconductor pattern 120, while a second sidewall of the one bit line BL may be in contact with a first impurity region 120S of another first semiconductor pattern 120. That is, two first semiconductor patterns 120 located at the same vertical level may be electrically connected to one bit line BL, but the inventive concepts is not limited thereto.

In addition, in the antifuse array region ACR, portions of the insulating layer 410 may be removed to form a first line opening ASLH and a second line opening ABLH, and an antifuse source line ASL and an antifuse bit line ABL may be respectively formed inside the first line opening ASLH and the second line opening ABLH. The antifuse source line ASL may be connected to the first impurity region 220S of the second semiconductor pattern 220, and the antifuse bit line ABL may be connected to the second impurity region 220D of the second semiconductor pattern 220.

In some embodiments, the bit line opening BLH, the first line opening ASLH, and the second line opening ABLH may all be formed by using the same process, and the bit line BL, the antifuse source line ASL, and the antifuse bit line ABL may all be formed by using the same process. In other embodiments, after a bit line opening BLH is first formed, a first line opening ASLH and a second line opening ABLH may be formed. In some other embodiments, after the bit line opening BLH and the second line opening ABLH are formed, the first line opening ASLH may be formed. In other embodiments, at least one of the bit line BL, the antifuse source line ASL, and the antifuse bit line ABL may be formed by using a process separate from at least one of the bit line BL, the antifuse source line ASL, and the antifuse bit line ABL.

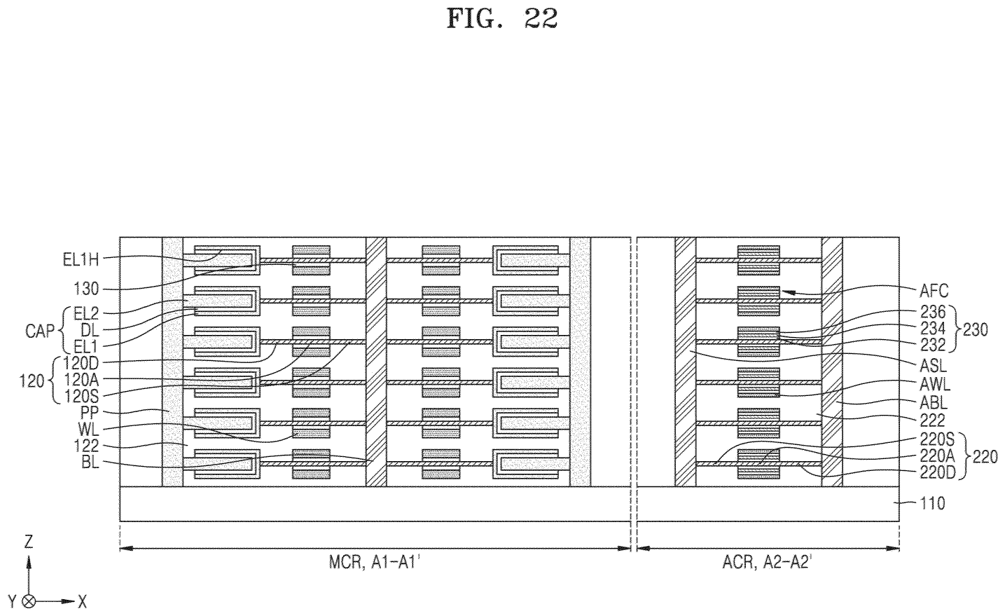

Referring to FIG. 22, the sacrificial mold layer SFL and the residual pattern 120R may be removed from the memory cell region MCR, and a cell capacitor CAP may be formed at a location from which the sacrificial mold layer SFL and the residual pattern 120R are removed.

In some embodiments, the cell capacitor CAP may include a first electrode EL1, a capacitor dielectric layer DL, and a second electrode EL2. The first electrode EL1 may be electrically connected to the second impurity region 120D of the first semiconductor pattern 120 and have an inner space EL1H extending in the first lateral direction X. The capacitor dielectric layer DL may be conformally located inside the inner space EL1H, and the inner space EL1H may be filled by the second electrode EL2. In some embodiments, the first electrode EL1, the capacitor dielectric layer DL, and/or the second electrode EL2 may be formed using an epitaxy process and/or an electrochemical process.

Additionally, a plate electrode PP may be formed to be electrically connected to the second electrode EL2 and extend in the second lateral direction Y.

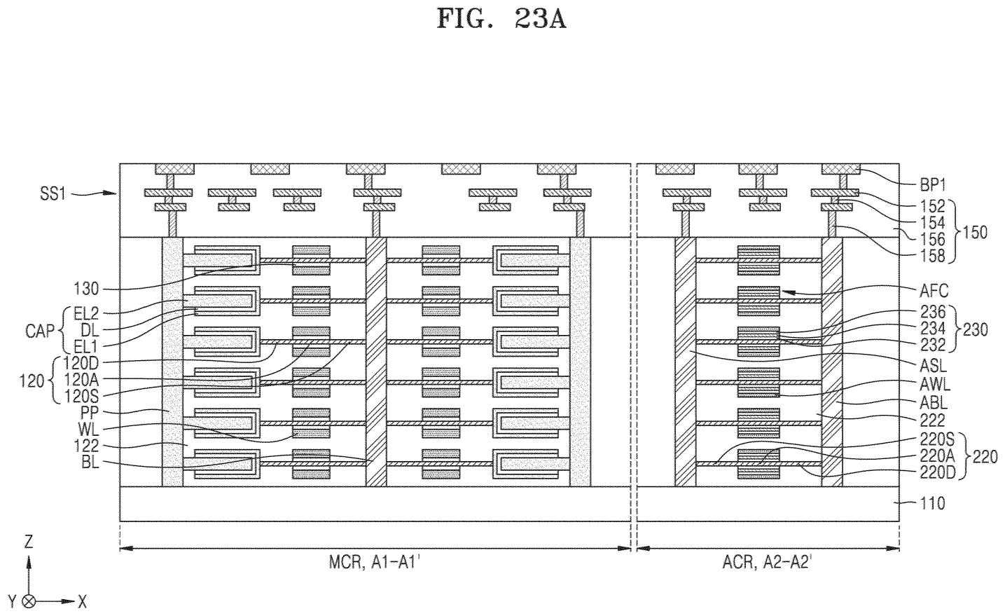

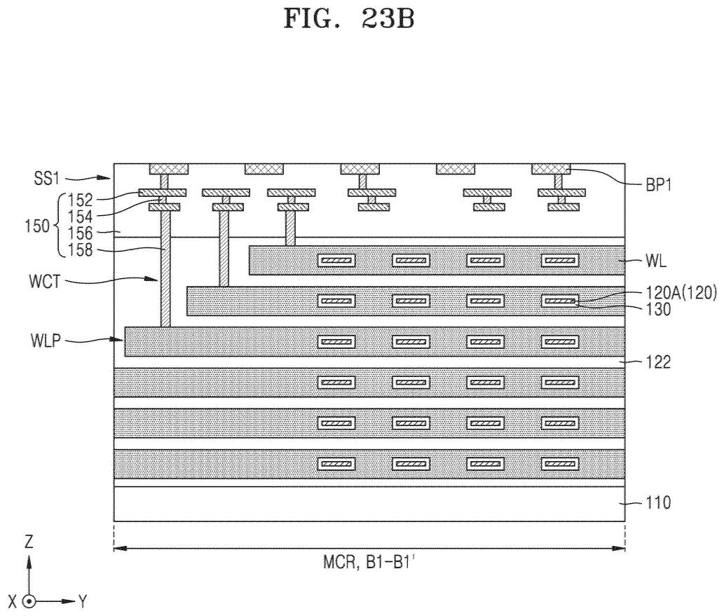

Referring to FIGS. 23A and 23B, an upper wiring structure 150 may be formed in the memory cell region MCR and the antifuse array region ACR. The upper wiring structure 150 may include a wiring layer 152, a via 154, an insulating layer 156, and a contact 158. For example, the contact 158 may be electrically connected to the bit line BL, the word line WL, and the plate electrode PP. Thereafter, a first bonding pad BP1 may be formed on the upper wiring structure 150 and located on the same plane as an uppermost surface of the insulating layer 156.

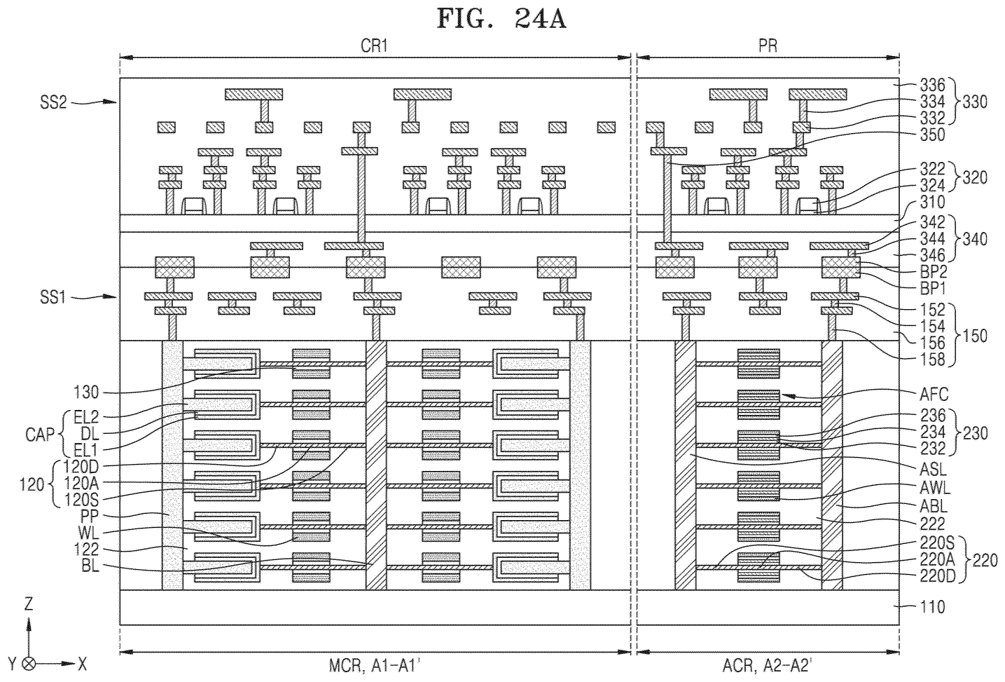

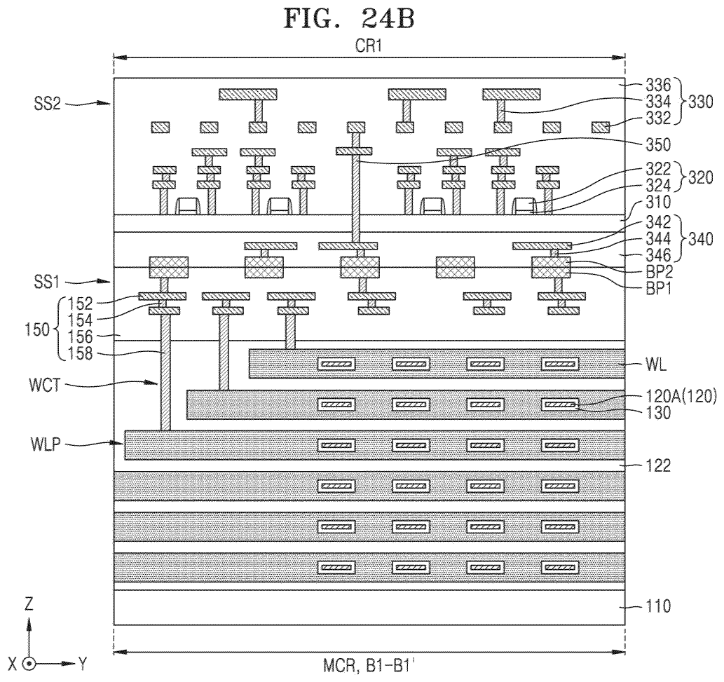

Referring to FIGS. 24A and 24B, a second stack structure SS2 may be provided.

In embodiments, the second stack structure SS2 may include a second substrate 310, a peripheral circuit transistor 320 on the second substrate 310, a front wiring structure 330 covering the peripheral circuit transistor 320 on a top surface of the second substrate 310, and a rear wiring structure 340 on a bottom surface of the second substrate 310.

In some embodiments, the peripheral circuit transistor 320 may be formed on a first surface (or the top surface) of the second substrate 310, the front wiring structure 330 may be formed on the first surface of the second substrate 310, and a carrier substrate may be adhered onto the front wiring structure 330. Thereafter, a second surface (or the bottom surface) of the second substrate 310 may be ground to thin the second substrate 310. Thereafter, the rear wiring structure 340 and a second bonding pad BP2 may be formed on the second surface of the second substrate 310, and thus, the formation of the second stack structure SS2 may be completed.

Afterwards, the second stack structure SS2 may be bonded to a first stack structure SS1. In this case, the first bonding pad BP1 of the first stack structure SS1 may be bonded to the second bonding pad BP2 of the second stack structure SS2, and a top surface of the insulating layer 156 may be bonded to a bottom surface of an insulating layer 346.

In a semiconductor memory device according to the inventive concepts, an antifuse array region included in a first stack structure may be at a location vertically overlapping a peripheral circuit region included in a second stack structure, and an antifuse cell in the antifuse array region may be driven in a charge trapping manner and may be formed simultaneously by using at least some operations included in a process of manufacturing memory cells included in a memory cell region of the first stack structure. Accordingly, the spatial efficiency of a chip including a 3D semiconductor memory device may improve.

While the inventive concepts have been particularly shown and described with reference to embodiments thereof, it will be understood that various changes in form and details may be made therein without departing from the spirit and scope of the following claims.

What is claimed is:

1. A semiconductor memory device comprising:
a first stack structure comprising a memory cell region and an antifuse array region,
the memory cell region comprising a plurality of memory cells and a plurality of cell capacitors, the plurality of memory cells and the plurality of cell capacitors arranged three-dimensionally, and
the antifuse array region comprising a plurality of antifuse cells arranged three-dimensionally; and
a second stack structure on the first stack structure, the second stack structure comprising a core region and a peripheral circuit region,
the core region at a location vertically overlapping the memory cell region, the core region being electrically connected to the memory cell region, and
the peripheral circuit region at a location vertically overlapping the antifuse array region.

2. The semiconductor memory device of claim 1, wherein the first stack structure comprises:
a first substrate;
a stack of first semiconductor patterns on the first substrate in the memory cell region, the first semiconductor patterns extending in a first lateral direction;
a word line surrounding each of the first semiconductor patterns, the word line extending in a second lateral direction; and
a bit line connected to a first end portion of each of the first semiconductor patterns, the bit line extending in a vertical direction.

3. The semiconductor memory device of claim 2, wherein the plurality of cell capacitors are each connected to a second end portion of a respective one of the first semiconductor patterns, the second end portion opposite to the first end portion, and
the plurality of cell capacitors extend in the first lateral direction.

4. The semiconductor memory device of claim 2, wherein each of the plurality of antifuse cells comprises:
a second semiconductor pattern on the first substrate in the antifuse array region, the second semiconductor pattern extending in the first lateral direction;
an antifuse word line surrounding the second semiconductor pattern and extending in the second lateral direction; and
an antifuse gate insulating layer between the antifuse word line and the second semiconductor pattern.

5. The semiconductor memory device of claim 4, wherein the antifuse gate insulating layer comprises:
a tunneling dielectric layer on a top surface and a bottom surface of the second semiconductor pattern;
a blocking dielectric layer on the tunneling dielectric layer; and
a charge storage layer between the tunneling dielectric layer and the blocking dielectric layer.

6. The semiconductor memory device of claim 4, wherein each of the first semiconductor patterns has a first thickness in the vertical direction,
the second semiconductor pattern has a second thickness in the vertical direction, and
the second thickness is equal to the first thickness of a respective one of the first semiconductor patterns.

7. The semiconductor memory device of claim 4, wherein the number of the first semiconductor patterns arranged in the vertical direction is equal to the number of the second semiconductor patterns arranged in the vertical direction.

8. The semiconductor memory device of claim 4, wherein the second semiconductor pattern is at a same level as a corresponding one of the first semiconductor patterns.

9. The semiconductor memory device of claim 1, wherein each of the plurality of antifuse cells has a first threshold voltage in a programmed state and a second threshold voltage in an unprogrammed state, and
the second threshold voltage is lower than the first threshold voltage.

10. A semiconductor memory device comprising:
a first stack structure comprising a plurality of memory cells and a plurality of antifuse cells,
the plurality of memory cells on a first substrate and spaced apart from each other in a vertical direction, and
the plurality of antifuse cells on the first substrate and spaced apart from each other in the vertical direction; and
a second stack structure on the first stack structure, the second stack structure comprising a core region and a peripheral circuit region,
the core region on a second substrate, the core region at a location vertically overlapping and electrically connected to the plurality of memory cells, and
the peripheral circuit region on the second substrate, the peripheral circuit region at a location vertically overlapping the plurality of antifuse cells,
wherein the plurality of memory cells comprise a plurality of first semiconductor patterns extending in a first lateral direction, and
the plurality of antifuse cells comprise a plurality of second semiconductor patterns extending in the first lateral direction and each respectively at a same vertical level as a corresponding first semiconductor pattern of the plurality of first semiconductor patterns.

11. The semiconductor memory device of claim 10, wherein the first stack structure further comprises:
a word line surrounding each of the plurality of first semiconductor patterns, the word line extending in a second lateral direction;
a bit line connected to a first end portion of each of the plurality of first semiconductor patterns, the bit line extending in the vertical direction; and
a plurality of cell capacitors respectively connected to second end portions of the plurality of first semiconductor patterns.

12. The semiconductor memory device of claim 11, wherein each of the plurality of antifuse cells comprises:
an antifuse word line surrounding a respective second semiconductor pattern of the plurality of second semiconductor patterns and extending in the second lateral direction; and
an antifuse gate insulating layer between the antifuse word line and the respective second semiconductor pattern.

13. The semiconductor memory device of claim 12, wherein the antifuse gate insulating layer comprises:
a tunneling dielectric layer on a top surface and a bottom surface of the respective second semiconductor pattern;
a blocking dielectric layer on the tunneling dielectric layer; and
a charge storage layer between the tunneling dielectric layer and the blocking dielectric layer.

14. The semiconductor memory device of claim 10, wherein each of the plurality of first semiconductor patterns has a first thickness in the vertical direction, and
each of the plurality of second semiconductor patterns has a second thickness in the vertical direction, and
the second thickness is equal to the first thickness of a respective one of the plurality of first semiconductor patterns.

15. The semiconductor memory device of claim 10, wherein the number of first semiconductor patterns arranged in the vertical direction is equal to the number of second semiconductor patterns arranged in the vertical direction.

16. The semiconductor memory device of claim 10, wherein each of the plurality of antifuse cells has a first threshold voltage in a programmed state and a second threshold voltage in an unprogrammed state, and
the second threshold voltage is lower than the first threshold voltage.

17. A semiconductor memory device comprising:
a first substrate;
a plurality of first semiconductor patterns on the first substrate, the plurality of first semiconductor patterns extending in a first lateral direction;
a word line on at least portions of each of the plurality of first semiconductor patterns, the word line extending in a second lateral direction;
a bit line connected to first end portions of each of the plurality of first semiconductor patterns, the bit line extending in a vertical direction;
a plurality of cell capacitors respectively connected to second end portions of the plurality of first semiconductor patterns;
a plurality of second semiconductor patterns spaced apart from the plurality of first semiconductors patterns on the first substrate, the plurality of second semiconductor patterns extending in the first lateral direction;
an antifuse word line on at least portions of each of the plurality of second semiconductor patterns, the antifuse word line extending in the second lateral direction;
a second substrate at a higher vertical level than the first substrate; and
a peripheral circuit transistor on the second substrate, the peripheral circuit transistor vertically overlapping the antifuse word line.

18. The semiconductor memory device of claim 17, further comprising:
an antifuse gate insulating layer between the plurality of second semiconductor patterns and the antifuse word line,
wherein the antifuse gate insulating layer comprises
a tunneling dielectric layer on a top surface and a bottom surface of each of the plurality of second semiconductor patterns;
a blocking dielectric layer on the tunneling dielectric layer; and
a charge storage layer between the tunneling dielectric layer and the blocking dielectric layer.

19. The semiconductor memory device of claim 17, wherein the number of first semiconductor patterns arranged in the vertical direction is equal to the number of second semiconductor patterns arranged in the vertical direction.

20. The semiconductor memory device of claim 17, wherein each of the plurality of first semiconductor patterns has a first thickness in the vertical direction,
each of the plurality of second semiconductor patterns has a second thickness in the vertical direction, and
the second thickness is equal to the first thickness of a corresponding one of the plurality of first semiconductor patterns.
